(19) United States
(12) Patent Application Publication
(10) Pub. No.: US 2008/0233827 A1
(43) Pub. Date: Sep. 25, 2008

(54) METHOD FOR MANUFACTURING DISPLAY DEVICE

(75) Inventors: Keiichi Kagami, Miyagi (JP); Keisuke Matsuo, Kanagawa (JP); Kokichi Kohinata, Kanagawa (JP); Eisuke Matsuda, Kanagawa (JP)

Correspondence Address: BELL, BOYD & LLOYD, LLP, P. O. BOX 1135, CHICAGO, IL, 60690, US

(73) Assignee: SONY CORPORATION, Tokyo (JP)

(21) Appl. No.: 12/051,603

(22) Filed: Mar. 19, 2008

(30) Foreign Application Priority Data
Mar. 20, 2007 (JP) P2007-072965

(51) Int. Cl. H05B 33/10

(52) U.S. Cl. 445/24

(57) ABSTRACT

Disclosed herein above is a method for manufacturing a display device, the method including the steps of: forming a transfer layer containing an organic light-emitting material over a support substrate by coating; heat-treating the transfer layer over the support substrate; and thermally transferring the heat-treated transfer layer over a device substrate.

### CROSS REFERENCES TO RELATED APPLICATIONS

The present application claims priority to Japanese Patent Application JP 2007-072965 filed in the Japan Patent Office on Mar. 20, 2007, the entire contents of which being incorporated herein by reference.

### BACKGROUND

The present application relates to a method for manufacturing a display device, and particularly to a method for manufacturing a display device that employs organic electroluminescence elements and is allowed to keep sufficiently-high light-emission efficiency and a sufficiently-long luminance half-life even if a coating film-deposition method and a thermal transfer method are applied to formation of a light-emitting layer thereof.

An organic electroluminescence element, which employs the electroluminescence of an organic material, is formed by providing an organic layer arising from stacking of a hole transport layer and a light-emitting layer between a lower electrode and an upper electrode, and is attracting attention as a light-emitting element that can emit light with high luminance by low-voltage DC driving.

A full-color display device employing such an organic electroluminescence element is obtained by arranging organic electroluminescence elements of red (R), green (G), and blue (B) over a substrate. In manufacturing of such a display device, at least light-emitting layers each composed of an organic light-emitting material for light emission of a respective one of the colors need to be formed as patterns for each light-emitting element. The formation of the pattern of the light-emitting layer is performed by e.g. a shadow masking method, in which a light-emitting material is deposited by evaporation or coating through a mask formed by providing an aperture pattern in a sheet, or an ink-jet method.

However, in the case of the pattern formation by shadow masking, processing of a further-miniaturized aperture pattern in the mask is difficult, and pattern formation in the light-emitting element area with high positional accuracy is difficult due to the deflection and extension of the mask. Therefore, further miniaturization and further enhancement in the integration degree for organic electroluminescence elements are difficult. Furthermore, due to the contact of the mask having an aperture pattern, previously-formed functional layers mainly formed of organic layers are easily damaged, which is a factor in the lowering of the manufacturing yield.

As for the pattern formation by an ink-jet method, miniaturization and enhancement in the integration degree for light-emitting elements, and increasing of the substrate size are difficult due to the limit of the patterning accuracy.

For that reason, as a novel method for pattern formation of light-emitting layers and other functional layers composed of organic materials, a transfer method employing an energy source (heat source) (i.e., thermal transfer method) has been proposed. Manufacturing of a display device by use of the thermal transfer method is carried out as follows for example. Initially, a lower electrode is formed over the substrate of the display device (hereinafter, referred to as a device substrate). On the other hand, over another substrate (hereinafter, referred to as a transfer substrate), a light-emitting layer is deposited with the intermediary of a photothermal conversion layer. Subsequently, the device substrate and the transfer substrate are so disposed that the light-emitting layer and the lower electrode face each other, and the backside of the transfer substrate is irradiated with laser light to thereby thermally transfer the light-emitting layer onto the lower electrode over the device substrate. In this step, the transfer substrate is scanned with spot-beam laser light, which allows the light-emitting layer to be thermally transferred only onto a predetermined area on the lower electrode with high positional accuracy (refer to Japanese Patent Laid-Open No. 2002-110350 (Patent Document 1) for this manufacturing method).

However, although the use of such a thermal transfer method is advantageous in miniaturization of light-emitting elements, this method involves a problem of yielding light-emitting elements that have lower light-emission efficiency and a shorter luminance half-life compared with light-emitting elements manufactured by a shadow mask method.

To address this problem, as a method for manufacturing a display device by using the thermal transfer method, there has been proposed a method in which thermal transfer is carried out by radiant-ray irradiation in such a way that a device substrate and a transfer substrate are heated, to thereby improve the light-emission efficiency and the luminance half-life (refer to Japanese Patent Laid-Open No. 2003-229259 (Patent Document 2)). In addition, there has also been proposed a method in which the deterioration of light-emitting layers due to oxygen and water vapor is prevented by heat-treating a device substrate after thermal transfer, to thereby improve the light-emission efficiency and the luminance life (refer to Japanese Patent Laid-Open No. 2006-66375 (Patent Document 3)).

In related arts, the film deposition of a light-emitting layer and so forth over a transfer substrate is performed by vacuum evaporation. On the other hand, as a method for enhancing the material use efficiency and the productivity, there has been proposed a method in which a coated film is formed by coating or printing a solution prepared by dissolving an organic light-emitting material in a solvent (refer to Japanese Patent Laid-Open No. 2005-500652 (Patent Document 4)).

However, in the case of the film deposition of a light-emitting layer and so forth over a transfer substrate by coating, there is a problem that the light-emission efficiency and the luminance life may not be sufficiently improved even if heat treatment at the time of transfer like that described in Patent Document 2 or heat treatment after transfer like that described in Patent Document 3 is carried out.

### SUMMARY

It is desirable to provide a method for manufacturing a display device in which light-emitting elements that each include a light-emitting layer arising from a transfer layer containing an organic material have high light-emission efficiency and a long luminance half-life even if the transfer layer is formed as a pattern over a device substrate by thermal transfer after being formed over a support substrate by coating.

According to an embodiment, there is provided a method for manufacturing a display device. In the method, initially a transfer layer containing an organic light-emitting material is formed over a support substrate by coating. Subsequently, the transfer layer is heat-treated. Furthermore, the heat-treated transfer layer is thermally transferred over a device substrate.

A lower electrode is formed over the device substrate to which the transfer layer is to be thermally transferred, and the transfer layer is transferred as a pattern onto this lower electrode. Thereafter, other functional layers and an upper electrode are so formed as to be stacked over the transfer layer, to thereby provide a light-emitting element (organic electroluminescence element) obtained by interposing the transfer layer containing the organic light-emitting material between the lower electrode and the upper electrode.

It is proved that the following advantages are achieved by this manufacturing method. Specifically, due to the procedure in which the thermal transfer is carried out after the transfer layer formed by coating is heat-treated, the thermally-transferred transfer layer has higher film density compared with the case of performing no heat treatment, and thus a light-emitting element including this transfer layer as its light-emitting layer has enhanced light-emission efficiency and an extended luminance life.

As described above, an embodiment allows achievement of a display device in which light-emitting elements that each include a light-emitting layer arising from a transfer layer containing an organic light-emitting material have high light-emission efficiency and a long luminance half-life even if the transfer layer is formed as a pattern over a device substrate by thermal transfer after being formed over a support substrate by coating. As a result, display device manufacturing can be realized in which a coating method offering more favorable material use efficiency and productivity compared with evaporation is applied to the formation of the transfer layer over the support substrate. Thus, reduction in the cost of the display device can be achieved.

Additional features and advantages are described herein, and will be apparent from the following Detailed Description and the figures.

### BRIEF DESCRIPTION OF THE FIGURES

FIG. 1 is a flowchart showing a manufacturing procedure according to an embodiment;

FIG. 2 is a sectional view of a transfer substrate fabricated in the embodiment;

FIGS. 3A to 3F are sectional views showing steps in a manufacturing method according to the embodiment;

FIGS. 4A and 4B are diagrams showing one example of the circuit configuration in a display device according to the embodiment;

FIG. 5 is a configuration diagram showing a module-shape display device having a sealed structure to which the embodiment is applied;

FIG. 6 is a perspective view showing a television to which the embodiment is applied;

FIGS. 7A and 7B are diagrams showing a digital camera to which the embodiment is applied: FIG. 7A is a front-side perspective view and FIG. 7B is a rear-side perspective view;

FIG. 8 is a perspective view showing a laptop personal computer to which the embodiment is applied;

FIG. 9 is a perspective view showing a video camera to which the embodiment is applied; and

FIGS. 10A to 10G are diagrams showing a cellular phone as portable terminal apparatus to which the embodiment is applied: FIGS. 10A and 10B are a front view and side view, respectively, of the opened state, and FIGS. 10C, 10D, 10E, 10F, and 10G are a front view, left-side view, right-side view, top view, and bottom view, respectively, of the closed state.

### DETAILED DESCRIPTION

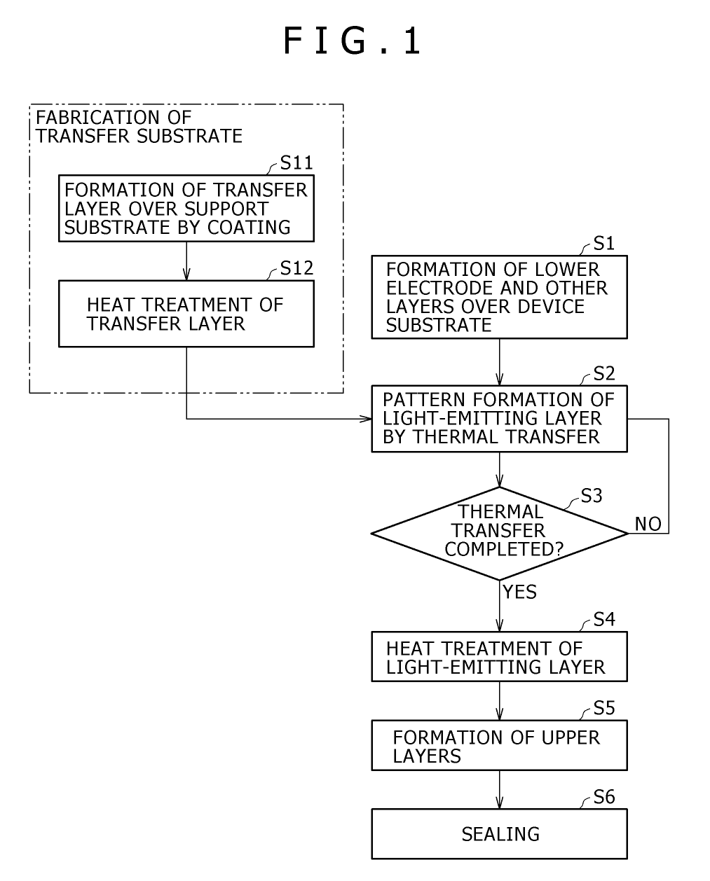

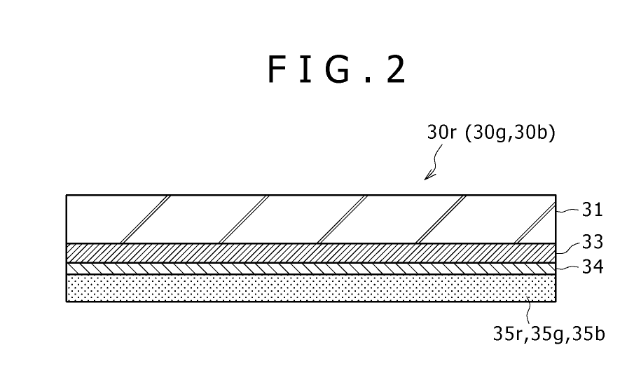

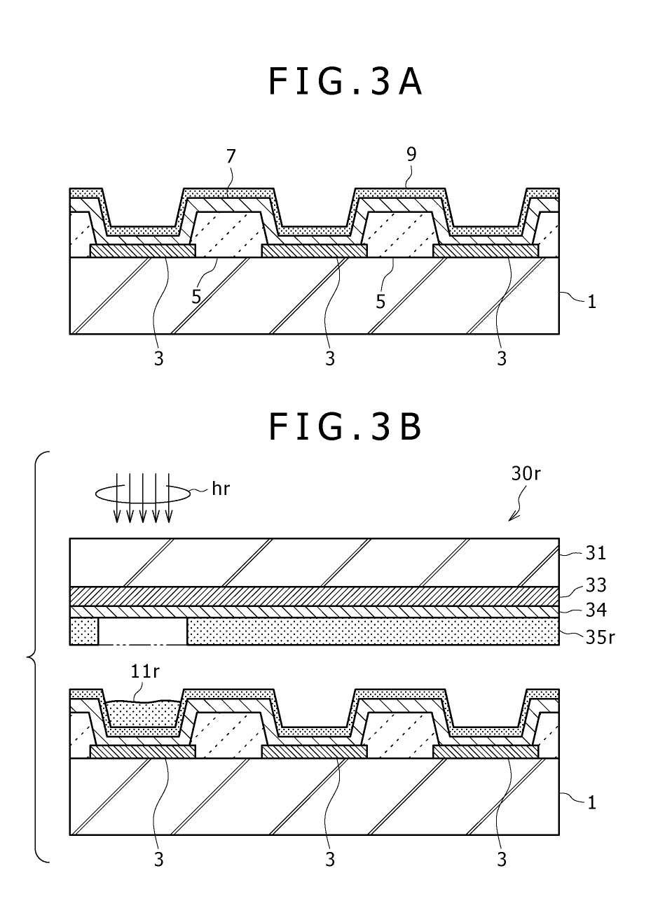

With reference to the flowchart of FIG. 1 and the sectional step diagrams of FIGS. 2 to 3, a description will be made below regarding an embodiment directed to manufacturing of a full-color display device formed by arranging organic electroluminescence elements that emit light of red (R), green (G), and blue (B) over a substrate.

Initially, prior to formation of the organic electroluminescence elements over a device substrate (steps S1 to S6), transfer substrates used in thermal transfer of light-emitting layers of the respective colors are fabricated on a color-by-color basis in steps S11 and S12.

<Fabrication of Red Transfer Substrate: Step S11>

For fabrication of a red transfer substrate, initially in the step S11, a transfer substrate obtained by forming a transfer layer over a support substrate by coating is fabricated. Specifically, referring to FIG. 2, initially a support substrate 31 is prepared. The support substrate 31 is composed of a material that has sufficient smoothness, optical transparency, and resistance to the temperatures in heat treatment, and specifically formed of a glass substrate, quartz substrate, optically-transparent ceramic substrate, or the like. Alternatively, a resin substrate may be used as long as there is no problem in its dimensional controllability against the heating temperatures.

Subsequently, across the entire surface over the support substrate 31, a red transfer layer 35r is formed by coating as a transfer layer for forming a red light-emitting layer, with the intermediary of a photothermal conversion layer 33 and an anti-oxidation film 34.

It is preferable to use, as the material of the photothermal conversion layer 33, a material having low reflectivity with respect to the wavelength range of laser light used as a heat source in the subsequent thermal transfer step. For example, when laser light with a wavelength of about 800 nm from a solid-state laser light source is employed, chromium (Cr), molybdenum (Mo), or the like is preferable as the material having low reflectivity and a high melting point, although the material is not limited to these metals. In the present embodiment, the photothermal conversion layer 33 is formed by depositing Mo to a film thickness of 200 nm by sputtering.

Examples of the material of the anti-oxidation layer 34 include SiNₓ and SiO₂. In the present embodiment, the anti-oxidation layer 34 is formed by using chemical vapor deposition (CVD).

The red transfer layer 35r is composed mainly of a host material having hole-transport capability and a red luminescent guest material (organic light-emitting material). The guest material may be either a fluorescent material or phosphorescent material. However, a fluorescent material is preferable in terms of easiness of control of the light-emission characteristic. For example, such a red transfer layer 35r contains as its host material α-NPD (α-naphthyl phenyl diamine), which is a hole transport material, and specifically is formed to a film thickness of about 45 nm by using α-NPD doped with 30-wt. % 2,6≡bis[(4′≡methoxydiphenylamino)styryl]≡1,5≡dicyanonaphthalene (BSN) as the red luminescent guest material.

The formation of the red transfer layer 35r by coating over the support substrate 31 is carried out by the following method. Specifically, the material obtained by mixing 30-wt. % BSN with α-NPD is dissolved in toluene at a solute concentration of 1 wt. %, to thereby prepare a solution. Subsequently, by using a spin-coater, the solution is dropped over the support substrate 31 over which the above-described photothermal conversion layer 33 and anti-oxidation layer 34 have been formed, with the substrate 31 rotated at a rotation speed of 1,500 rpm, to thereby form a coated film. Under this condition, the solvent (toluene) is evaporated during the rotation, so that a dried coated film of the red transfer layer 35r is obtained.

<Step S12>

In the subsequent step S12, the red transfer layer 35r formed over the support substrate 31 by coating is heat-treated. This heat treatment is carried out at a temperature that is equal to or higher than the glass transition point of an organic material of the red transfer layer 35r and is lower than the melting point of the organic material. For example, in the present embodiment, α-NPD is used as the major material of the red transfer layer 35r, and the glass transition point and melting point of α-NPD are 96° C. and 285° C., respectively. Therefore, the heat treatment is performed at a temperature in the range from the glass transition point of α-NPD as the major material to the melting point thereof, and specifically performed at 150° C. for 30 minutes for example. This heat treatment is performed in an inert atmosphere, including a vacuum state.

<Fabrication of Green Transfer Substrate: Step S11>

A green transfer substrate 30g is also fabricated in a similar manner. Specifically, initially in the step S11, a green transfer layer 35g is formed by coating as a transfer layer for forming a green light-emitting layer across the entire surface over the support substrate 31 with the intermediary of the photothermal conversion layer 33 and the anti-oxidation film 34. The configurations of the photothermal conversion layer 33 and the anti-oxidation film 34 may be the same as those of the red transfer substrate 30r.

The green transfer layer 35g is composed mainly of a host material having electron-transport capability and a green luminescent guest material (organic light-emitting material). The host material has higher electron-transport capability compared with the material of a hole transport layer, which will be described later. Specifically, the energy level of the highest occupied molecular orbit (HOMO) of the host material used for the green material layer is lower than that of the HOMO of α-NPD contained in the hole transport layer. More specifically, the difference between both the levels is 0.2 eV or higher. The guest material may be either a fluorescent material or phosphorescent material. However, a fluorescent material is preferable in terms of easiness of control of the light-emission characteristic.

Such a green transfer layer 35g is composed of e.g. a material obtained by doping ADN (anthracene dinaphtyl) as the electron-transport host material with 5-wt. % coumarin 6 as the green luminescent guest material, and is formed by coating to a film thickness of about 30 nm.

The formation of the green transfer layer 35g by coating over the support substrate 31 is carried out by the following method. Specifically, the material obtained by mixing 5-wt. % coumarin 6 with ADN is dissolved in toluene at a solute concentration of 0.8 wt. %, to thereby prepare a solution. Subsequently, by using a spin-coater, the solution is dropped over the support substrate 31 over which the above-described photothermal conversion layer 33 and anti-oxidation layer 34 have been formed, with the substrate 31 rotated at a rotation speed of 1,500 rpm, to thereby form a coated film. Under this condition, the solvent (toluene) is evaporated during the rotation, so that a dried coated film of the green transfer layer 35g is obtained.

<Step S12>

In the subsequent step S12, the green transfer layer 35g formed over the support substrate 31 by coating is heat-treated. This heat treatment is carried out at a temperature that is equal to or higher than the glass transition point of an organic material of the green transfer layer 35g and is lower than the melting point of the organic material. For example, in the present embodiment, ADN is used as the major material of the green transfer layer 35g, and the glass transition point and melting point of ADN are 106° C. and 389° C., respectively. Therefore, the heat treatment is performed at a temperature in the range from the glass transition point of ADN as the major material to the melting point thereof, and specifically performed at 160° C. for 30 minutes for example. This heat treatment is performed in an inert atmosphere, including a vacuum state.

<Fabrication of Blue Transfer Substrate: Step S 11>

A blue transfer substrate 30b is also fabricated in a similar manner. Specifically, initially in the step S11, a blue transfer layer 35b is formed by coating as a transfer layer for forming a blue light-emitting layer across the entire surface over the support substrate 31 with the intermediary of the photothermal conversion layer 33 and the anti-oxidation film 34. The configurations of the photothermal conversion layer 33 and the anti-oxidation film 34 may be the same as those of the red transfer substrate 30r.

The blue transfer layer 35b is composed mainly of a host material having electron-transport capability and a blue luminescent guest material (organic light-emitting material). Similarly to the above-described green transfer layer (35g), the host material has higher electron-transport capability compared with the material of the hole transport layer. As for the guest material, it may be either a fluorescent material or phosphorescent material. However, a fluorescent material is preferable in terms of easiness of control of the light-emission characteristic.

Such a blue transfer layer 35b is composed of e.g. a material obtained by doping ADN (anthracene dinapthyl) as the electron-transport host material with 2.5-wt. % 4,4′≡bis[2≡{4≡(N,N≡diphenylamino)phenyl}vinyl]biphenyl (DPAVBi) as the blue luminescent guest material, and is formed by coating to a film thickness of about 30 nm.

The formation of the blue transfer layer 35b by coating over the support substrate 31 is carried out by the following method. Specifically, the material obtained by mixing 2.5-wt. % DPAVBi with ADN is dissolved in toluene at a solute concentration of 0.8 wt. %, to thereby prepare a solution. Subsequently, by using a spin-coater, the solution is dropped over the support substrate 31 over which the above-described photothermal conversion layer 33 and anti-oxidation layer 34 have been formed, with the substrate 31 rotated at a rotation speed of 1,500 rpm, to thereby form a coated film. Under this condition, the solvent (toluene) is evaporated during the rotation, so that a dried coated film of the blue transfer layer 35b is obtained.

<Step S12>

In the subsequent step S12, the blue transfer layer 35b formed over the support substrate 31 by coating is heat-treated. This heat treatment is carried out at a temperature that is equal to or higher than the glass transition point of an organic material of the blue transfer layer 35b and is lower than the melting point of the organic material. For example, in the present embodiment, ADN is used as the major material of the blue transfer layer 35b similarly to the green transfer layer 35g, and therefore the heat treatment is performed at 160° C. for 30 minutes. This heat treatment is performed in an inert atmosphere, including a vacuum state.

By using the transfer substrates 30r, 30g, and 30b of the respective colors fabricated in the above-described manner, organic electroluminescence elements are formed over a device substrate in the steps S1 to S6 described below.

<Step S1>

As shown in FIG. 3A, initially lower electrodes 3 and so on are formed over a device substrate 1 in the step S1.

The device substrate 1 over which the organic electroluminescence elements are to be arranged is formed of a glass substrate, silicon substrate, plastic substrate, a thin film transistor (TFT) substrate on which TFTs are formed, or the like. If the display device to be manufactured is a transmissive type from which emitted-light is extracted through the substrate 1, this substrate 1 is formed by using a material having optical transparency.

In each pixel over this device substrate 1, the lower electrode 3 for supplying first charges is formed as a pattern. If the first charges are the positive charges, the lower electrode 3 is formed as the anode. On the other hand, if the first charges are the negative charges, the lower electrode 3 is formed as the cathode.

This lower electrode 3 is patterned into a suitable shape depending on the drive system of the display device to be manufactured. For example, if the drive system of the display device is a simple-matrix system, the lower electrode 3 is formed into e.g. a strip shape that is continuous across plural pixels. If the drive system of the display device is an active-matrix system in which each pixel is provided with a TFT, the patterns of the lower electrodes 3 are each formed corresponding to a respective one of the plural arranged pixels. Furthermore, each lower electrode 3 is connected to a corresponding one of the TFTs, which are each provided in a respective of the pixels similarly, via a contact hole (not shown) formed in an interlayer insulating film that covers these TFTs.

For the lower electrode 3, a suitable material is selected and used depending on the light-extraction system of the display device to be manufactured. Specifically, if this display device is a top-emission type from which emitted-light is extracted through the opposite side to the substrate 1, the lower electrode 3 is formed by using a highly-reflective material. On the other hand, if this display device is a transmissive type or dual-emission type from which emitted-light is extracted through the substrate 1, the lower electrode 3 is formed by using an optically-transparent material.

In the present embodiment, the display device is a top-emission type, and the first charges are the positive charges and hence the lower electrode 3 is used as the anode. In this case, the lower electrode 3 is formed by using any of the following conductive materials with high reflectivity and alloys of the materials: silver (Ag), aluminum (Al), chromium (Cr), iron (Fe), cobalt (Co), nickel (Ni), copper (Cu), tantalum (Ta), tungsten (W), platinum (Pt), and gold (Au).

If the display device is a top-emission type and the lower electrode 3 is used as the cathode (i.e., the first charges are the negative charges), the lower electrode 3 is formed by using a conductive material having a low work function. As such a conductive material, e.g. an alloy of an active metal such as Li, Mg, or Ca and a metal such as Ag, Al, or In, or a multilayer structure of any of these metals can be used. Furthermore, between the lower electrode 3 and a functional layer thereon, e.g. a thin layer composed of a compound between an active metal such as Li, Mg, or Ca and a halogen such as fluorine or bromine, oxygen, or the like may be interposed.

If the display device is a transmissive type or dual-emission type and the lower electrode 3 is used as the anode, the lower electrode 3 is formed by using a conductive material having high transmittance, such as indium tin oxide (ITO) or indium zinc oxide (IZO).

If an active-matrix system is employed as the drive system of the display device to be manufactured, it is desirable that the display device be a top-emission type for ensuring of a high aperture ratio of the organic electroluminescence elements.

After the formation of the above-described lower electrodes 3 (anodes, in the present embodiment), a pattern of an insulating film 5 is so formed as to cover the peripheries of these lower electrodes 3. The partial portions of the lower electrodes 3 exposed through the windows formed in this insulating film 5 correspond to pixel areas in which the respective organic electroluminescence elements are to be provided. This insulating film 5 is composed of an organic insulating material such as polyimide or photoresist, or an inorganic insulating material such as a silicon oxide.

Thereafter, a first-charge injection layer (i.e., hole injection layer, in the present embodiment) 7 is formed as a common layer covering the lower electrodes 3 and the insulating film 5. Such a hole injection layer 7 is formed by using a general hole injection material. As one example, it is formed by depositing m-MTDATA [4,4,4-tris(3-methylphenylphenylamino)triphenylamine] by evaporation to a film thickness of 10 nm.

Subsequently, a first-charge transport layer (i.e., hole transport layer, in the present embodiment) 9 is formed as a common layer covering the hole injection layer 7. Such a hole transport layer 9 is formed by using a general hole transport material. As one example, it is formed by depositing α-NPD [4,4-bis(N-1-naphthyl-N-phenylamino)biphenyl] by evaporation to a film thickness of 35 nm. Examples of the general hole transport material of the hole transport layer 9 include benzine derivatives, styrylamine derivatives, triphenylmethane derivatives, and hydrazone derivatives.

Each of the hole injection layer 7 and the hole transport layer 9 may be formed to have a multilayer structure formed of plural layers.

<Step S2>

In the subsequent step S2, as shown in FIG. 3B, a red light-emitting layer 11r arising from the red transfer layer is formed as a pattern by thermal transfer over the lower electrode 3 in a part of the pixels.

For this pattern formation, initially the red transfer substrate 30r fabricated through the steps S11 and S12 is disposed to face the device substrate 1 over which the hole transport layer 9 has been formed. Specifically, the red transfer substrate 30r and the device substrate 1 are so disposed that the red transfer layer 35r and the hole transport layer 9 face each other. Furthermore, the red transfer substrate 30r is brought into tight contact with the device substrate 1. Even in this case, the red transfer substrate 30r is not in contact with the partial portions of the hole transport layer 9 over the lower electrodes 3 because the red transfer layer 35r is supported over the insulating film 5 on the device substrate 1.

Subsequently, the backside of the red transfer substrate 30r disposed to face the device substrate 1 in such a state is irradiated with a laser hr having a wavelength of e.g. 800 nm. In this irradiation, the areas corresponding to the pixels in which the red light-emitting elements are to be formed are selectively irradiated with a spot beam of the laser light hr.

This irradiation causes the photothermal conversion layer 33 to absorb the laser light hr, and by using the heat generated due to the light absorption, the red transfer layer 35r is thermally transferred to the substrate 1. Through this step, on the hole transport layer 9 deposited over the substrate 1, the pattern of the red light-emitting layer 11r that has hole-transport capability and arises from the thermal transfer of the red transfer layer 35r with high positional accuracy is formed.

In this step, it is important that the irradiation with the laser light hr be so carried out that the area over the lower electrode 3 exposed through the insulating film 5 in the formation area of the red light-emitting element (pixel area) will be completely covered by the red light-emitting layer 11r.

In the subsequent step S3, it is determined whether or not patterns of the light-emitting layers have been formed for all the pixels and hence the thermal transfer has been completed. Unless it is determined that the thermal transfer has been completed (YES) in the step S3, the manufacturing sequence returns to the step S2 repeatedly.

Through the repetition of the step S2, as shown in FIGS. 3C and 3D, patterns of a green light-emitting layer 11g and a blue light-emitting layer 11b are sequentially formed over the lower electrodes 3 in the other pixels, in which the red light-emitting layer 11r is not formed. These green and blue light-emitting layers 11g and 11b are sequentially formed by a transfer method similarly to the formation of the above-described red light-emitting layer 11r.

Specifically, as shown in FIG. 3C, initially the green transfer substrate 30g fabricated through the steps S11 and S12 is disposed to face the device substrate 1 over which the hole transport layer 9 has been formed. In this state, through the green transfer substrate 30g, the areas corresponding to the pixels in which the green light-emitting elements are to be formed are selectively irradiated with a spot beam of the laser hr.

This irradiation forms the pattern of the green light-emitting layer 11g arising from the selective thermal transfer of the green transfer layer 35g on the hole transport layer 9 deposited over the device substrate 1. This thermal transfer is so carried out that the green light-emitting layer 11g will be formed in the state in which the respective materials of the green transfer layer 35g are substantially-homogeneously mixed with each other, similarly to the pattern formation of the red light-emitting layer 11r described with FIG. 3B.

Furthermore, as shown in FIG. 3D, the blue transfer substrate 30b fabricated through the steps S11 and S12 is disposed to face the substrate 1 over which the hole transport layer 9, the red light-emitting layer 11r, and the green light-emitting layer 11g have been formed. In this state, through the blue transfer substrate 30b, the areas corresponding to the pixels in which the blue light-emitting elements are to be formed are selectively irradiated with a spot beam of the laser hr.

This irradiation forms the pattern of the blue light-emitting layer 11b arising from the selective thermal transfer of the blue transfer layer 35b on the hole transport layer 9 deposited over the device substrate 1. This thermal transfer is so carried out that the blue light-emitting layer 11b will be formed in the state in which the respective materials of the blue transfer layer 35b are substantially-homogeneously mixed with each other, similarly to the pattern formation of the red light-emitting layer 11r described with FIG. 3B.

It is desirable that the thermal transfer step, which is repeated in the above-described manner, be carried out in a vacuum, although it can be carried out also under the atmospheric pressure. The execution of the thermal transfer in a vacuum allows transfer with use of laser having lower energy, which can reduce thermal adverse effects on the light-emitting layer to be transferred. Furthermore, the execution of the thermal transfer step in a vacuum is desirable because the degree of the contact between the substrates is enhanced and thus the patterning accuracy by the transfer becomes favorable. Moreover, if all the process is carried out in a vacuum continuously, the deterioration of the elements can be prevented.

The order of the three times of thermal transfer step, which is repeated for the respective colors as described above, may be any order.

<Step S3>

In the step S3, it is determined whether or not all the thermal transfer steps have been completed. If it is determined that the steps have been completed (YES), the manufacturing sequence proceeds to the next step S4.

<Step S4>

Heat treatment in the step S4 is carried out at a temperature that is equal to or higher than the glass transition points of the organic materials of the light-emitting layers (transfer layers) 11r, 11g, and 11b of the respective colors and is lower than the melting points of the organic materials. In the present embodiment, the light-emitting layers 11r, 11g, and 11b of the respective colors, i.e., the transfer layers (35r, 35g, and 35b) of the respective colors, are formed by using different organic materials. Therefore, the heat treatment is performed at a temperature that is equal to or higher than the highest glass transition point among those of the major organic materials (e.g. host materials) of these transfer layers and is lower than the lowest melting point among those of these organic materials.

Furthermore, it is preferable that the heat treatment of the step S4 be carried out at a temperature lower than that of the heat treatment of the step S12 for fabricating the transfer substrates 30r, 30g, and 30b. If the heat treatment of the step S4 is carried out at a temperature higher than that of the heat treatment of the step S12, the reaction between the hole transport layer 9 and the light-emitting layers 11r, 11g, and 11b will occur unpreferably.

More preferably, the heat treatment is performed at a temperature that is lower than the melting points of the respective organic materials of the organic material layers formed over the device substrate 1, i.e., the hole injection layer 7, the hole transport layer 9, the red light-emitting layer 11r, the green light-emitting layer 11g, and the blue light-emitting layer 11b, and is around the glass transition points of the respective organic materials of the hole transport layer 9 and the red light-emitting layer 11r. Such heat treatment planarizes the exposed surfaces of the hole transport layer 9 and the red light-emitting layer 11r.

The “temperature around glass transition points” refers to a temperature within the range of ±30° C. with respect to an intermediate temperature between the glass transition point of the organic material mainly contained in the hole transport layer 9 and the glass transition points of the organic materials mainly contained in the red light-emitting layer 11r, the green light-emitting layer 11g, and the blue light-emitting layer 11b.

For example, in the present embodiment, α-NPD is used as the major material of the hole transport layer 9 and the red light-emitting layer 11r, and ADN is used as the major material of the green light-emitting layer 11g and the blue light-emitting layer 11b. The glass transition point of α-NPD is 96° C., and that of ADN is 106° C. Therefore, the heat treatment is performed at 100° C. for about 30 minutes for example. This heat treatment is performed in an inert atmosphere, including a vacuum state.

<Step S5>

After the step S4, upper layers are formed over the device substrate 1 in the step S5.

Initially, as shown in FIG. 3E, a second-charge transport layer (i.e. electron transport layer, in the present embodiment) 13 is so deposited as to cover the entire surface over the device substrate 1 over which the light-emitting layers 11r, 11g, and 11b have been formed. This electron transport layer 13 is deposited by evaporation as a common layer across the entire surface over the substrate 1. Such an electron transport layer 13 is formed by using a general electron transport material. As one example, it is formed by depositing 8≡hydroxyquinoline aluminum (Alq3) by evaporation to a film thickness of about 20 nm.

The hole injection layer 7, the hole transport layer 9, the light-emitting layers 11r, 11g, and 11b of the respective colors, and the electron transport layer 13 serve as an organic layer 15 as a whole.

Referring next to FIG. 3F, a second-charge injection layer (i.e. electron injection layer, in the present embodiment) 17 is deposited on the electron transport layer 13. This electron injection layer 17 is deposited by evaporation as a common layer across the entire surface over the device substrate 1. Such an electron injection layer 17 is formed by using a general electron injection material. As one example, it is formed by depositing LiF by vacuum evaporation to a film thickness of about 0.3 nm (at an evaporation rate of 0.01 nm/sec).

Subsequently, an upper electrode 19 is formed on the electron injection layer 17. This upper electrode 19 is used as the cathode if the lower electrode 3 is the anode, whereas it is used as the anode if the lower electrode 3 is the cathode. In the present embodiment, the upper electrode 19 is formed as the cathode.

If the display device to be manufactured is based on a simple-matrix system, the upper electrode 19 is formed into e.g. a strip shape that intersects with the strip shape of the lower electrode 3. On the other hand, if this display device is based on an active-matrix system, this upper electrode 19 is formed as a blanket film covering the entire surface over the substrate 1 and is used as an electrode common to the respective pixels. In this case, by forming an auxiliary electrode (not shown) at the same layer-level as that of the lower electrode 3 and connecting the upper electrode 19 to this auxiliary electrode, a configuration for preventing a voltage drop of the upper electrode 19 can be achieved.

At the intersections between the lower electrodes 3 and the upper electrode 19, red light-emitting elements 21r, green light-emitting elements 21g, and blue light-emitting elements 21b are formed corresponding to the respective areas in which the organic layer 15 including the light-emitting layers 11r, 11g, and 11b of the respective colors is sandwiched between the lower electrodes 3 and the upper electrode 19.

For the upper electrode 19, a suitable material is selected and used depending on the light-extraction system of the display device to be manufactured. Specifically, if this display device is a top-emission type or dual-emission type from which light emitted by the light-emitting layers 11r, 11g, and 11b is extracted through the opposite side to the device substrate 1, the upper electrode 19 is formed by using an optically- transmissive material or semi-transmissive material. On the other hand, if this display device is a bottom-emission type from which emitted-light is extracted only through the device substrate 1, the upper electrode 19 is formed by using a highly-reflective material.

In the present embodiment, the display device is a top-emission type, and the lower electrode 3 is used as the anode and therefore the upper electrode 19 is used as the cathode. In this case, for efficient electron injection to the organic layer 15, the upper electrode 19 is formed by using a material having favorable optical transparency among the low-work-function materials shown in the above description of the step for forming the lower electrode 3.

Specifically, for example, the upper electrode 19 is formed as a common cathode that is composed of MgAg and formed by vacuum evaporation to a film thickness of 10 nm. Used for the deposition of the upper electrode 19 is a deposition method in which the energy of deposition particles is so low that no influence is given to the underlying layers, such as evaporation or chemical vapor deposition (CVD).

If the display device is a top-emission type, it is preferable that the light-emitting elements be so designed that extracted-light will have enhanced intensity, by forming the upper electrode 19 composed of a semi-transmissive material and constructing a resonator structure between the upper electrode 19 and the lower electrode 3.

If the display device is a transmissive type and the upper electrode 19 is used as the cathode, the upper electrode 19 is formed by using a conductive material having a low work function and high reflectivity. If the display device is a transmissive type and the upper electrode 19 is used as the anode, the upper electrode 19 is formed by using a conductive material having high reflectivity.

<Step S6>

After the organic electroluminescence elements 21r, 21g, and 21b of the respective colors are formed in the above-described manner, the organic electroluminescence elements 21r, 21g, and 21b are sealed in the step S6. In the present embodiment, a protective film (not shown) is so deposited as to cover the upper electrode 19. This protective film is formed to a sufficiently-large film thickness by using a material with low water permeability and low water absorption in order to prevent water from reaching the organic layer 15. Furthermore, if the display device to be manufactured is a top-emission type, this protective film is formed by using a material that allows the transmission of light generated by the light-emitting layers 11r, 11g, and 11b: a transmittance of e.g. about 80% is ensured as that of the protective film.

Such a protective film may be formed by using an insulating material. In the case of forming the protective film by using an insulating material, an inorganic amorphous insulating material such as amorphous silicon (α—Si), amorphous silicon carbide (α—SiC), amorphous silicon nitride (α—Sil—xNx), or amorphous carbon (α—C) can be preferably used. Such an inorganic amorphous insulating material includes no grain and thus has low water permeability, and hence will serve as a favorable protective film.

For example, in the case of forming the protective film composed of an amorphous silicon nitride, it is formed by CVD to a film thickness of 2 to 3 μm. In this film deposition, it is desirable that the deposition temperature be set to a room temperature in order to prevent luminance lowering due to the deterioration of the organic layer 15 and the deposition condition be so set that the film stress is minimized in order to prevent separation of the protective film.

If the display device to be manufactured is based on an active-matrix system and the upper electrode 19 is provided as a common electrode covering the entire surface over the substrate 1, the protective film may be formed by using a conductive material. In the case of forming the protective film by using a conductive material, a transparent conductive material such as ITO or IZO is used.

Each of the above-described layers covering the light-emitting layers 11r, 11g, and 11b of the respective colors is formed into a blanket-film shape without using a mask.

It is important that the manufacturing process from the heat treatment of the transfer layers in the step S12 to the formation of the upper layers in the step S5, preferably to the formation of the protective film in the step S6, be carried out under a continuation of an inert atmosphere, including a vacuum state, without exposure to the air. Exposure of the transfer substrate and the device substrate to oxygen and water in the air in the middle of this manufacturing process should be avoided because the exposure causes the lowering of characteristics.

For the device substrate 1 over which the protective film has been formed in the above-described manner, a protective substrate is bonded to the protective film side with the intermediary of a resin material for the bonding. As the resin material for the bonding, e.g. a UV-curable resin is used. As the protective substrate, e.g. a glass substrate is used. If the display device to be manufactured is a top-emission type, the resin material for the bonding and the protective substrate should be formed by using a material having optical transparency.

Through the above-described steps, a full-color display device 23 obtained by arranging the light-emitting elements 21r, 21g, and 21b of the respective colors over the substrate 1 is completed.

As described above, in the fabrication of the transfer substrates in the manufacturing method of the present embodiment, the transfer layers 35r, 35g, and 35b are formed by coating over the respective support substrates 31 in the step S11 (see FIG. 2), and then the transfer layers 35r, 35g, and 35b are subjected to heat treatment in the step S12. Furthermore, in the step S2, the transfer layers 35r, 35g, and 35b are thermally transferred over the device substrate by using the thus fabricated transfer substrates. It is proved that this manufacturing sequence can enhance the light-emission efficiency of the organic electroluminescence elements and suppress the luminance deterioration of the elements.

As a result, display device manufacturing can be realized in which a coating method offering more favorable material use efficiency and productivity compared with evaporation is applied to the fabrication of the transfer substrates. Thus, reduction in the cost of the display device employing organic electroluminescence elements can be achieved.

In the above-described embodiment, the first and second charges are the positive and negative charges, respectively, and the lower electrode 3 and the upper electrode 19 are used as the anode and cathode, respectively. However, as an embodiment, a configuration is also available in which the first and second charges are the negative and positive charges, respectively, and the lower electrode 3 and the upper electrode 19 are used as the cathode and anode, respectively. In this case, the respective layers 7 to 17 between the lower electrode 3 and the upper electrode 19 are deposited in the reverse stacking order, and therefore the formation procedure for the layers is also reversed.

Furthermore, in the embodiment, spin-coating with use of a spin-coater is applied to the fabrication of the transfer substrates 30r, 30g, and 30b as the method for forming the transfer layers 35r, 35g, and 35b by coating over the support substrates 31, as described above with FIG. 2. However, for the formation of the transfer layers 35r, 35g, and 35b by coating, a coating system such as slit-coating or spray-coating or a printing system such as flexographic printing system, gravure offset printing system, or ink-jet system may be used.

In addition, in the formation of the transfer layers 35r, 35g, and 35b by coating, the layer may be formed as a pattern over the support substrate by using e.g. a printing system. In this case, by collectively irradiating a wide area with laser light in the thermal transfer of the step S2, the transfer layer formed as the pattern is collectively transferred to the areas corresponding to the intended pixels.

Alternatively, in the fabrication of the transfer substrates 30r, 30g, and 30b, the photothermal conversion layer 33 may be formed as a pattern on the support substrate 31 and the transfer layers 35r, 35g, and 35b may be formed across the entire surface by coating over the pattern with the intermediary of the anti-oxidation layer 34. Also in this case, by collectively irradiating a wide area with laser light in the thermal transfer of the step S2, the transfer layer as a pattern is collectively transferred to the areas corresponding to the intended pixels.

More alternatively, as another embodiment, in the fabrication of the transfer substrates 30r, 30g, and 30b, patterns of the respective transfer layers 35r, 35g, and 35b containing plural kinds of organic light-emitting materials may be formed over the same support substrate 31. Over this support substrate 31, a marker for alignment of the respective transfer layers 35r, 35g, and 35b formed as the patterns is also disposed.

In this case, the heat treatment in the step S12 is carried out at a temperature that is equal to or higher than the glass transition points of organic materials of the respective transfer layers 35r, 35g, and 35b and is lower than the melting points of the organic materials. Therefore, e.g. the lowest temperature among the heat treatment temperatures individually designed for the respective transfer layers 35r, 35g, and 35b is employed. In the case of the above-described embodiment, the heat treatment temperature in the step S12 for the red transfer layer 35r is 150° C. and the heat treatment temperature in the step S12 for the green transfer layer 35g and the blue transfer layer 35b is 160° C. Therefore, the heat treatment temperature in the step S12 is set to 150° C. for the case in which patterns of three kinds of transfer layers 35r, 35g, and 35b are formed over the same support substrate 31.

Also in the case of using the thus fabricated transfer substrate, by collectively irradiating a wide area with laser light in the thermal transfer of the step S2, the transfer layers formed as the patterns are transferred to the areas corresponding to the intended pixels. Moreover, the plural kinds of transfer layers 35r, 35g, and 35b can be thermally transferred to the device substrate collectively by one time of thermal transfer. Also in this case, a sufficient effect of enhancing characteristics can be achieved compared with the case in which heat treatment is not carried out for the transfer layers over the support substrate 31.

The above-described embodiments are effective and can offer the same advantages also for an element that includes layers arising from separation of the above-described common layers and for a tandem organic EL element obtained by stacking organic layer units including a light-emitting layer (light-emitting units) as shown in e.g. Japanese Patent Laid-Open No. 2003-272860.

Furthermore, in the above-described embodiments, in addition to the heat treatment of the transfer layers 35r, 35g, and 35b over the support substrate 31 (step S12), the heat treatment for the light-emitting layers 11r, 11g, and 11b arising from thermal transfer of these transfer layers over the device substrate (step S4) is carried out. Such two times of heat treatment can further enhance the characteristics of the organic electroluminescence elements compared with the case of performing the heat treatment of the step S12.

<<Schematic Configuration of Display Device>>

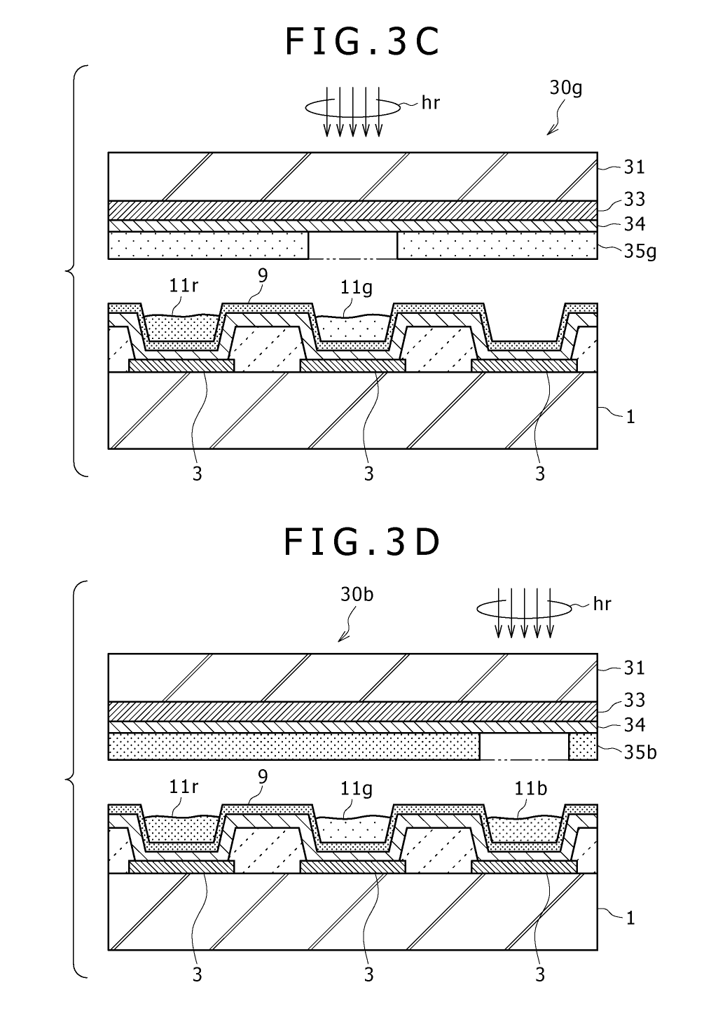

FIG. 4 is a diagram showing one example of the entire configuration of the display device 23 manufactured by the above-described embodiment. FIG. 4A is a schematic configuration diagram of the display device 23, and FIG. 4B is a diagram showing the configuration of a pixel circuit in the display device 23. The following description will deal with an example in which the embodiment is applied to a display device of an active-matrix system.

As shown in FIG. 4A, a display area 1a and a peripheral area 1b are defined on the device substrate 1 of this display device 23. The display area 1a is formed as a pixel array part in which plural scan lines 41 and plural signal lines 43 are provided along the horizontal direction and the vertical direction, respectively, and one pixel a is provided corresponding to each of the intersections between these lines. In each of the pixels a, any of the organic electroluminescence elements 21r, 21g, and 21b shown in FIG. 3F is provided. Provided in the peripheral area 1b are a scan line drive circuit b for scan-driving the scan lines 41 and a signal line drive circuit c for supplying video signals (i.e. input signals) dependent upon luminance information to the signal lines 43.

As shown in FIG. 4B, the pixel circuit provided in each pixel a includes e.g. any one of the organic electroluminescence elements 21r, 21g, and 21b, a drive transistor Tr1, a write transistor (sampling transistor) Tr2, and a holding capacitor Cs. Due to driving by the scan line drive circuit b, a video signal written from the signal line 43 via the write transistor Tr2 is held in the holding capacitor Cs, and the current dependent upon the amount of the held signal is supplied from the drive transistor Tr1 to the organic electroluminescence element 21r, 21g, or 21b, so that the organic electroluminescence element 21r, 21g, or 21b emits light with the luminance dependent upon the current value.

This pixel circuit configuration is merely one example, and the pixel circuit may further include an additional capacitive element and plural transistors according to need. Furthermore, a requisite drive circuit is added to the peripheral area 1b according to the change of the pixel circuit.

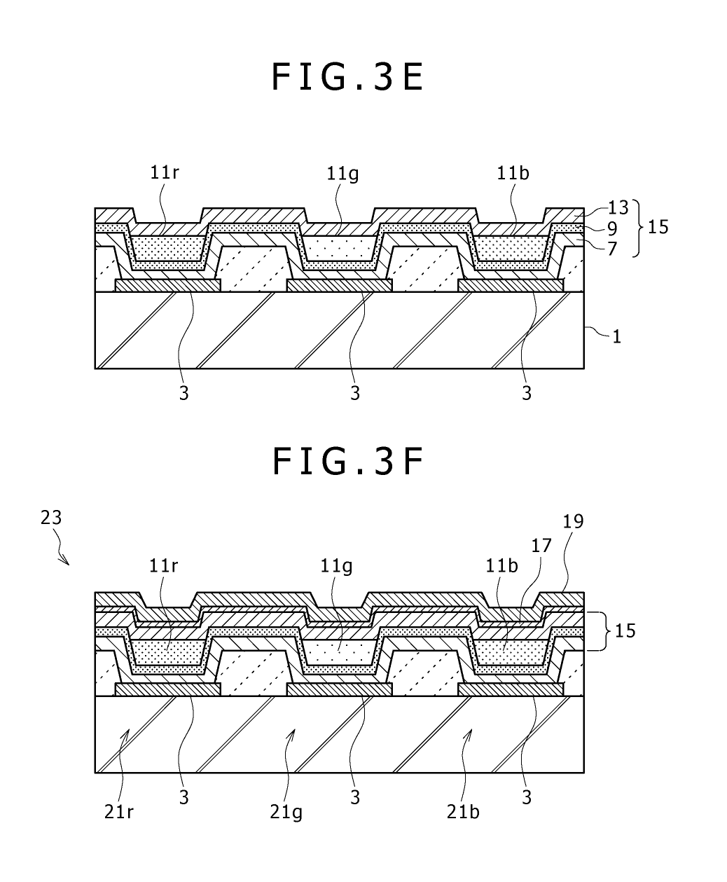

The display device according to the above-described embodiment encompasses also a module-shape display device having a sealed structure like that shown in FIG. 5. For example, the display module shown in FIG. 5 is formed by providing a sealing part 51 surrounding the display area 1a as a pixel array part and bonding the substrate including the display area 1a to a counter member (sealing substrate 52) such as a transparent glass substrate by use of the sealing part 51 as an adhesive. This transparent sealing substrate 52 may be provided with a color filer, protective film, light-shielding film, and so on. The device substrate 1 as the display module on which the display area 1a is formed may be provided with a flexible printed board 53 for input/output of signals and so on to/from the display area 1a (pixel array part) from/to the external.

<<Application Examples>>

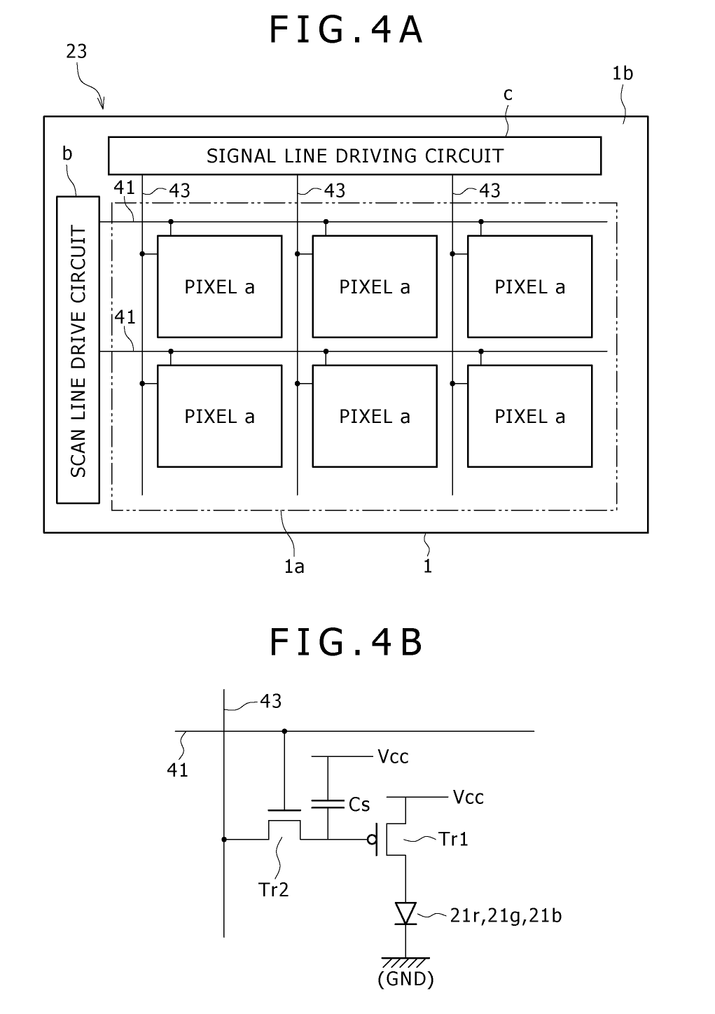

The display device according to the above-described embodiment can be applied to various kinds of electronic apparatus shown in FIGS. 6 to 10. Specifically, the display device can be used as a display part in electronic apparatus in any field that displays a video signal input thereto or produced therein as an image and video, such as a digital camera, laptop personal computer, and portable terminal apparatus typified by a cellular phone, and video camera. Examples of electronic apparatus to which the embodiment is applied will be described below.

FIG. 6 is a perspective view showing a television to which the embodiment is applied. This television includes a video display screen 101 composed of a front panel 102, a filter glass 103, and so on, and is fabricated by using the display device according to the embodiment as the video display screen 101.

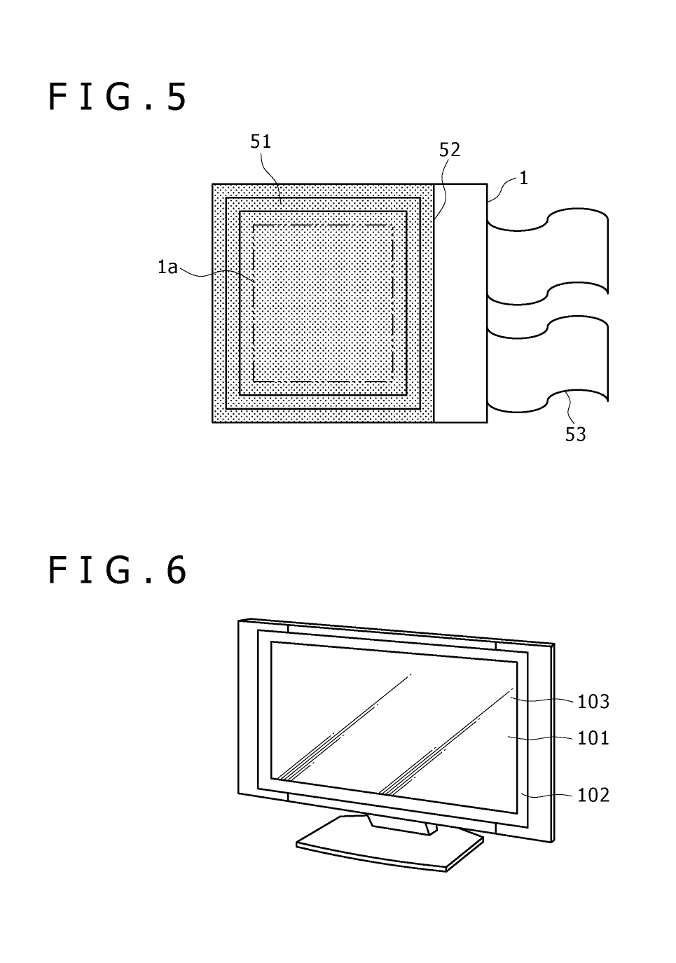

FIG. 7 is a diagram showing a digital camera to which the embodiment is applied: FIG. 7A is a front-side perspective view and FIG. 7B is a rear-side perspective view. This digital camera includes a light emitter 111 for flash, a display part 112, a menu switch 113 and a shutter button 114, and is fabricated by using the display device according to the embodiment as the display part 112.

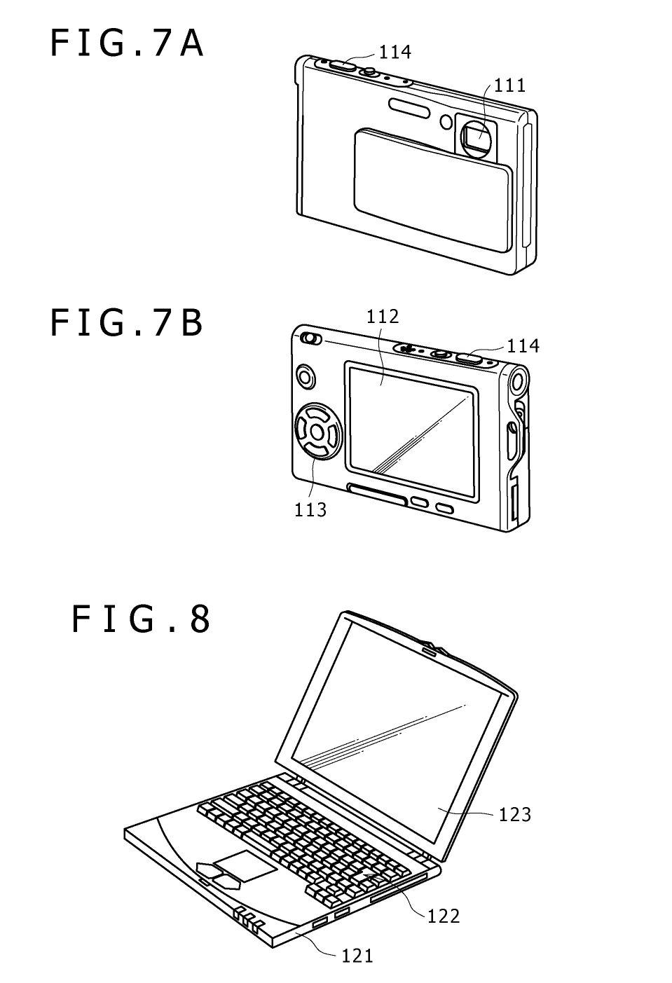

FIG. 8 is a perspective view showing a laptop personal computer to which the embodiment is applied. This laptop personal computer includes in a main body 121 thereof a keyboard 122 operated in inputting of characters and so forth and a display part 123 for displaying images. The laptop personal computer is fabricated by using the display device according to the embodiment as the display part 123.

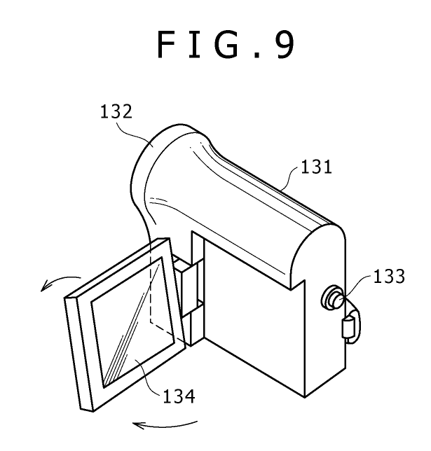

FIG. 9 is a perspective view showing a video camera to which the embodiment is applied. This video camera includes a main body 131, a lens 132 that is disposed on the front side of the camera and used to capture a subject image, a start/stop switch 133 regarding imaging and a display part 134. The video camera is fabricated by using the display device according to the embodiment as the display part 134.

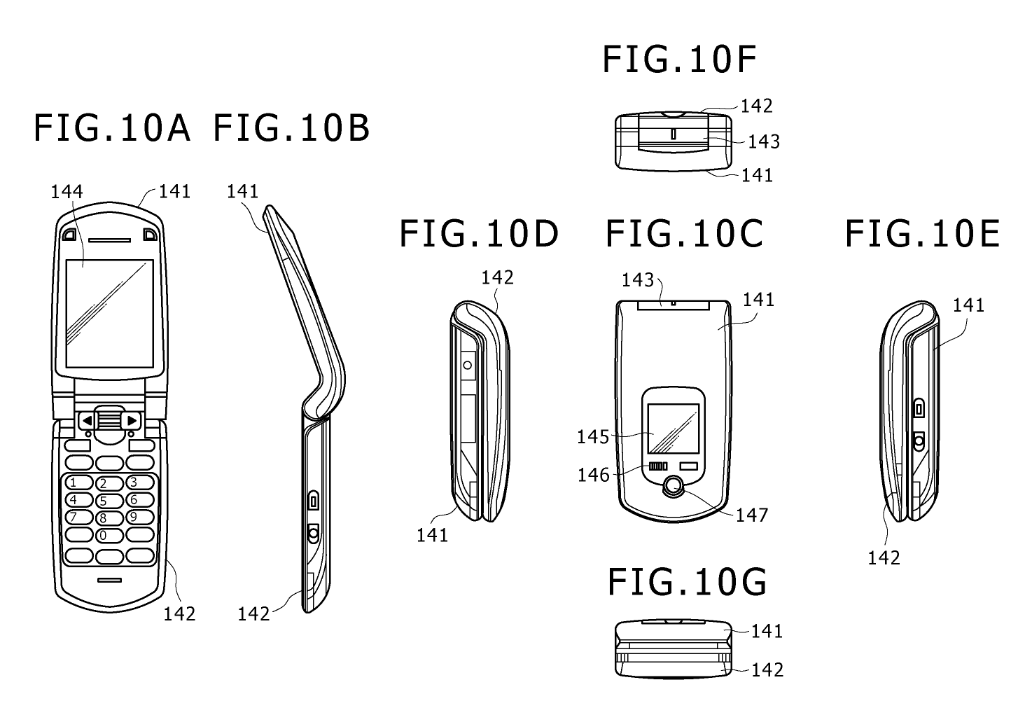

FIG. 10 is a diagram showing a cellular phone as portable terminal apparatus to which the embodiment is applied: FIGS. 10A and 10B are a front view and side view, respectively, of the opened state, and FIGS. 10C, 10D, 10E, 10F, and 10G are a front view, left-side view, right-side view, top view, and bottom view, respectively, of the closed state. This cellular phone includes an upper casing 141, a lower casing 142, a connection (hinge) 143, a display 144, a sub-display 145, a picture light 146, a camera 147, and so on. The cellular phone is fabricated by using the display device according to the embodiment as the display 144 and the sub-display 145.

[Working Examples]

As a specific working example and a comparative example for the working example, organic electroluminescence elements that are included in a full-color display device and emit light of the respective colors were manufactured. In the following, the manufacturing procedure and evaluation results of these elements will be described.

<<Working Example>>

The light-emitting elements 21r, 21g, and 21b of the respective colors included in the display device were individually fabricated as follows based on the embodiment (see FIGS. 1 to 3).

<Fabrication of Red Light-Emitting Element 21r>

(Step S11)

On a glass substrate as the support substrate 31, the photothermal conversion layer 33 composed of molybdenum with a thickness of 200 nm was deposited by general sputtering. Subsequently, on the photothermal conversion layer 33, the anti-oxidation layer 34 composed of a silicon nitride SiNₓ was deposited by CVD to a film thickness of 100 nm.

Subsequently, the red transfer layer 35r was formed by coating. For the formation, a solution was prepared by dissolving α-NPD doped with 30-wt. % BSN in toluene at a solute concentration of 1 wt. %. Subsequently, by using a spin-coater, the solution was dropped over the glass substrate over which the above-described photothermal conversion layer and anti-oxidation layer had been formed, with the substrate rotated at a rotation speed of 1,500 rpm, to thereby form a coated film (red transfer layer 35r).

(Step S12)

The red transfer layer 35r formed by coating was subjected to heat treatment. α-NPD was used as the major material of the red transfer layer 35r, and the glass transition point of α-NPD is 96° C. Therefore, the heat treatment was carried out at a temperature in the range from this glass transition point to the melting point of α-NPD. Specifically, the heat treatment was performed at 150° C. for 30 minutes in a nitrogen gas.

(Step S1)

On a glass substrate as the device substrate 1, patterns of the lower electrodes 3 were formed as the anodes. The lower electrode 3 had a two-layer structure obtained by forming an APC (Ag—Pd—Cu) layer as a silver alloy layer (having a thickness of 120 nm) and a transparent conductive layer composed of ITO (having a thickness of 10 nm) in that order. Subsequently, the insulating film 5 composed of a silicon oxide was so deposited by sputtering to a thickness of about 2 μm as to cover the lower electrodes 3, and then the lower electrodes 3 were exposed by lithography, to thereby define pixel areas. On the surface thereof, m-MTDATA was deposited by evaporation as the hole injection layer 7 to a film thickness of 10 nm. Subsequently, α-NPD was deposited by evaporation as the hole transport layer 9 to a film thickness of 35 nm.

(Step S2)

The red transfer substrate 30r fabricated through the steps S11 and S12 was disposed over the device substrate 1 in such a way that the deposited organic layers faced each other, and these substrates were brought into tight contact with each other in a vacuum. A small gap of about 2 μm was kept between both the substrates due to the thickness of the insulating film 5. In this state, areas corresponding to pixel areas over the device substrate 1 were irradiated with a laser beam having a wavelength of 800 nm through the transfer substrate 30r to thereby thermally transfer the red transfer layer 35r from the transfer substrate 30r, so that the hole-transport red light-emitting layer 11r was formed. The spot size of the laser beam was set to 300 μm×10 μm. The laser beam was moved for scanning in the direction perpendicular to the longitudinal direction of the beam. The energy density was set to 1.8 J/cm².

(Step S4)

The whole of the device substrate 1 over which the pattern of the hole-transport red light-emitting layer 11r had been formed by the thermal transfer was subjected to heat treatment for 30 minutes. In the heat treatment, the temperature was set to 100° C. because the glass transition point of α-NPD of the hole transport layer 9 is 96° C.

(Step S5)

After the heat treatment, the electron transport layer 13 was deposited. As the electron transport layer 13, 8≡hydroxyquinoline aluminum (Alq3) was deposited by evaporation to a film thickness of about 20 nm. Subsequently, as the electron injection layer 17, LiF was deposited by evaporation to a film thickness of about 0.3 nm (at an evaporation rate of 0.01 nm/sec). Subsequently, MgAg was deposited by evaporation to a film thickness of 10 nm for the upper electrode 19 serving as the cathode, so that the red light-emitting element 21r was obtained.

<Fabrication of Green Light-Emitting Element 21g>

As the transfer substrate 30g fabricated through the steps S11 and S12, the substrate obtained by replacing the hole-transport red transfer layer 35r by the electron-transport green transfer layer 35g was prepared.

(Step S11)

The green transfer layer 35g was formed by coating as follows. Specifically, ADN as the host material was doped with 5-wt. % coumarin 6 as the green luminescent guest material. The resultant material was dissolved in toluene at a solute concentration of 0.8 wt. % to thereby prepare a solution. Subsequently, the solution was dropped over the support substrate 31 over which the photothermal conversion layer 33 and the anti-oxidation layer 34 had been deposited, with the substrate 31 rotated by using a spin-coater at a rotation speed of 1,500 rpm, to thereby form a coated film (green transfer layer 35g).

(Step S12)

The green transfer layer 35g formed by coating was heat-treated. ADN was used as the major material of the green transfer layer 35g, and the glass transition point of ADN is 106° C. Therefore, the heat treatment was carried out at a temperature in the range from this glass transition point to the melting point of ADN. Specifically, the heat treatment was performed at 160° C. for 30 minutes in a nitrogen gas.

The steps S1 to S5 were carried out similarly to the fabrication of the red light-emitting element with use of the thus fabricated green transfer substrate 30g, so that the green light-emitting element 21g was obtained. In the heat treatment of the step S4, the temperature was set to 100° C., which was lower than that in the step S12.

<Fabrication of Blue Light-Emitting Element 21b>

As the transfer substrate 30b fabricated through the steps S11 and S12, the substrate obtained by replacing the hole-transport red transfer layer 35r by the electron-transport blue transfer layer 35b was prepared.

(Step S11)

The blue transfer layer 35b was formed by coating as follows. Specifically, ADN as the host material was doped with 2.5-wt. % DPAVBi as the blue luminescent guest material. The resultant material was dissolved in toluene at a solute concentration of 0.8 wt. % to thereby prepare a solution. Subsequently, the solution was dropped over the support substrate 31 over which the photothermal conversion layer 33 and the anti-oxidation layer 34 had been deposited, with the substrate 31 rotated by using a spin-coater at a rotation speed of 1,500 rpm, to thereby form a coated film (blue transfer layer 35b).

(Step S12)

The blue transfer layer 35b formed by coating was heat-treated. ADN was used as the major material of the blue transfer layer 35b, and the glass transition point of ADN is 106° C. Therefore, the heat treatment was carried out at a temperature in the range from this glass transition point to the melting point of ADN. Specifically, the heat treatment was performed at 160° C. for 30 minutes in a nitrogen gas.

The steps S1 to S5 were carried out similarly to the fabrication of the red light-emitting element with use of the thus fabricated blue transfer substrate 30b, so that the blue light-emitting element 21b was obtained. In the heat treatment of the step S4, the temperature was set to 100° C., which was lower than that in the step S12.

<<Comparative Example>>

The light-emitting elements of the respective colors included in a display device were individually fabricated in such a way that the heat treatment of the step S12 and the heat treatment of the step S4 carried out in the above-described working example were omitted.

<<Evaluation Results>>

Regarding the light-emitting elements of the respective colors fabricated in the above-described manner as the working example and the comparative example, the chromaticity (CIE-x, CIE-y) and the light-emission efficiency were measured by using a spectral radiance meter. The measurement was performed in the state in which a current with a constant current density of 10 mA/cm² was applied to the respective light-emitting elements. Furthermore, the life test was carried out in such a way that the current application was so set that the light-emitting elements of the same color between the working example and the comparative example emit light with the same luminance. In this life test, the luminance decrease rate after the elapse of 100 hours was measured. These evaluation results are shown in Table 1.

TABLE 1

| | | | | Light- | 100 h |
|---|---|---|---|---|---|
| | | | | emission | luminance |
| | | | | efficiency | decrease rate |
| | | CIE-x | CIE-y | [Cd/A] | [%] |
| Red light- | Working | 0.64 | 0.32 | 7.70 | 10 |
| emitting | example | | | | |
| element | (Comparative | 0.63 | 0.32 | 5.99 | 28 |
| | example) | | | | |
| Green | Working | 0.22 | 0.66 | 18.56 | 12 |
| light- | example | | | | |
| emitting | (Comparative | 0.22 | 0.68 | 16.24 | 35 |
| element | example) | | | | |
| Blue light- | Working | 0.16 | 0.31 | 7.53 | 15 |
| emitting | example | | | | |
| element | (Comparative | 0.16 | 0.33 | 6.59 | 42 |
| | example) | | | | |

As shown in Table 1, regarding the red light-emitting element, it was found that the light-emission efficiency of the element fabricated as the working example was higher by about 30% than that of the element fabricated as the comparative example, specifically, the light-emission efficiency was greatly enhanced from 5.99 [Cd/A] to 7.7 [Cd/A]. In addition, also in the luminance decrease rate as a criterion of the light-emission life, great improvement from 28% to 10% was found.

Furthermore, also regarding the green light-emitting element and the blue light-emitting element, it was found that the element fabricated as the working example achieved great improvement in the light-emission efficiency and the light-emission life represented as the luminance decrease rate compared with the element fabricated as the comparative example.

From the above-described results, it is proved that the following advantages can be achieved by manufacturing a display device by using the method according to the embodiment. Specifically, even if a transfer layer is deposited by coating in fabrication of a transfer substrate, all of red, green, and blue light-emitting elements are allowed to have enhanced light-emission efficiency while keeping a long luminance half-life, and thus a full-color display device is allowed to have enhanced displaying performance.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A method for manufacturing a display device, the method comprising:
forming a transfer layer containing an organic light-emitting material over a support substrate by coating;
heat-treating the transfer layer over the support substrate; and
thermally transferring the heat-treated transfer layer over a device substrate.

2. The method for manufacturing the display device according to claim 1, wherein
the transfer layer is heat-treated at a temperature that is equal to or higher than a glass transition point of an organic material of the transfer layer and is lower than a melting point of the organic material.

3. The method for manufacturing the display device according to claim 1, wherein
the transfer layer is heat-treated in an inert atmosphere.

4. The method for manufacturing the display device according to claim 1, wherein
the transferred layer is heat-treated over the device substrate.

5. The method for manufacturing the display device according to claim 4, wherein
the transferred layer is heat-treated at a temperature that is equal to or higher than the glass transition point of the organic material of the transfer layer and is lower than the melting point of the organic material.

6. The method for manufacturing the display device according to claim 5, wherein
the heat treatment of the transferred layer over the device substrate is performed at a temperature lower than the temperature of the heat treatment of the transfer layer over the support substrate.

7. The method for manufacturing the display device according to claim 1, wherein
a lower electrode is formed over the device substrate, the transfer layer is thermally transferred over the lower electrode, and an upper electrode is formed over the transferred layer.

8. The method for manufacturing the display device according to claim 7, further comprising the step of
forming a protective film over the upper electrode, wherein
a process from the thermally transfer of the transfer layer to the forming of the protective film is continuously carried out in an inert atmosphere.

9. The method for manufacturing the display device according to claim 1, wherein
the transfer layer is formed to cover an entire surface of the support substrate, and
a part of the transfer layer is transferred over the device substrate.

10. The method for manufacturing the display device according to claim 1, wherein
the transfer layer is formed as a pattern over the support substrate, and
the transfer layer formed as the pattern is collectively transferred over the device substrate.

11. The method for manufacturing the display device according to claim 10, wherein
a plurality of kinds of transfer layers containing different kinds of organic light-emitting materials are formed as patterns over the support substrate.

12. The method for manufacturing the display device according to claim 1, wherein
a photothermal conversion layer is formed as a pattern between the support substrate and the transfer layer, and
the transfer layer formed over the photothermal conversion layer is transferred over the device substrate.
